(19) United States
(12) Patent Application Publication
(10) Pub. No.: US 2024/0297266 A1
(43) Pub. Date: Sep. 5, 2024

(54) METHOD OF MANUFACTURING ALUMINUM NITRIDE LAYER

(71) Applicant: WAVELORD CO., LTD, Suwon-si (KR)

(72) Inventor: June O SONG, Suwon-si (KR)

(73) Assignee: WAVELORD CO., LTD, Suwon-si (KR)

(21) Appl. No.: 18/575,331

(22) PCT Filed: Jul. 4, 2022
(86) PCT No.: PCT/KR2022/009600

§ 371 Date: Dec. 29, 2023

(30) Foreign Application Priority Data
Jul. 2, 2021 (KR) 10-2021-0086955

(51) Int. Cl. H01L 33/00; H01L 33/12

(52) U.S. Cl. CPC H01L 33/007; H01L 33/0093; H01L 33/12

(57) ABSTRACT

The present disclosure relates to a method of manufacturing an aluminum nitride, the method comprising the steps of: preparing a growth substrate; growing an Al1−v−wGavInwN (0≤v<1, 0≤w<1, v+w<1) layer on the growth substrate; conducting etching so that the Al1−v−wGavInwN (0≤v<1, 0≤w<1, v+w<1) layer becomes a porous Al1−v−wGavInwN (0≤v<1, 0≤w<1, v+w<1) layer with a plurality of voids through decomposition and vaporization of gallium (Ga) and indium (In) therein; forming a plurality of voids in the growth substrate by using the porous Al1−v−wGavInwN (0≤v<1, 0≤w<1, v+w<1) layer as an etching mask; and growing an AlN layer on the porous Al1−v−wGavInwN (0≤v<1, 0≤w<1, v+w<1) layer.

### TECHNICAL FIELD

The present disclosure relates to a method of manufacturing an aluminum nitride (AlN) layer, and particularly, to a method of manufacturing an AlN layer having no cracks and a low crystallographic defect density. The manufactured AlN layer or AlN template can be used to grow an aluminum (Al)-containing semiconductor layer and typically can be used to manufacture LEDs, LDs, HEMTs, piezoelectric thin films, and the like. Particularly, it can be used in ultraviolet light-emitting diodes (UV LEDs) and UVC or deep UV light-emitting semiconductor diodes. UVC or deep UV refers to light typically having a wavelength of 200 to 340 nm, and in some cases, also refers to light having a wavelength of 200 to 400 nm. Here, the light-emitting semiconductor diode refers to a semiconductor optical diode that generates light through recombination of electrons and holes, and an example thereof includes Group III-nitride light-emitting semiconductor diodes. The Group III-nitride semiconductor is composed of a compound represented by AlₓGa_{y}In_{1-x-y}N (0≤x≤1, 0≤y≤1, 0≤x+y≤1), and the inclusion of other elements is not excluded. The light-emitting semiconductor diode may be in the form of a wafer and a chip.

### BACKGROUND ART

This section provides background information related to the present disclosure, which is not necessarily prior art.

FIG. 1 shows an example of an ultraviolet (UV) light-emitting semiconductor diode disclosed in U.S. Pat. No. 9,627,580, and the light-emitting semiconductor diode includes a growth substrate 10 (e.g., a sapphire substrate), an aluminum nitride (AlN) layer 20 (e.g., high temperature (HT)-grown AlN), a first semiconductor region 30 (e.g., an n-type AlGaN layer), an active region 40 (e.g., AlGaN/AlGaN MQWs) that generates light through recombination of electrons and holes, an electron blocking layer 50 (e.g., p-type AlGaN), a second semiconductor region 60 (e.g., p-type (Al)GaN), a first ohmic electrode 70 (e.g., Cr/Ni), a first pad electrode 75 (e.g., Au), a current diffusion electrode 80 (e.g., a light-transmitting electrode (ITO) or a reflective electrode (Al/Ni)), and a second pad electrode 85 (e.g., Cr/Ni/Au or Au). In the case of the light-emitting semiconductor diode in the form shown in FIG. 1, when a light-transmitting material is used as the current diffusion electrode 80 and the first pad electrode 75 and the second pad electrode 85 are used as wire bonding pads, it is referred to as a lateral chip, and when a reflective electrode is used as the current diffusion electrode 80 and the first pad electrode 75 and the second pad electrode 85 are used as flip bonding pads, it is referred to as a flip chip. Meanwhile, when the growth substrate 10 is removed and the first pad electrode 75 is formed on the first semiconductor region 60 from which the growth substrate 10 has been removed, it is referred to as a vertical chip (e.g., US Registered U.S. Pat. No. 10,263,140).

In manufacture of UV light-emitting semiconductor diodes, as a wavelength of UV light is shortened, an aluminum (Al) content in the semiconductor regions 30, 40, 50, and 60 increases, and accordingly, the use of an AlN substrate as the growth substrate 10 is ideal in view of the coefficient of thermal expansion and lattice constant. However, since the AlN substrate is very expensive and does not have the light transmittance that light-emitting diodes require, an AlN template manufactured by forming an AlN layer 20 with a thickness of 2 μm or more on a sapphire growth substrate 10 which is a single crystal of aluminum oxide (Al2O3) having excellent light transmittance in the UV wavelength range has been used. In order to manufacture such an AlN template, tensile stress caused by the difference in lattice constant and thermal expansion coefficient between the sapphire growth substrate 10 and the HT AlN layer 20 needs to be appropriately relieved, otherwise, fine microcracking occurs inside the AlN layer 20 with a thickness of 2 μm or more. Typically, an HT AlN layer 20 of a 2D growth mode is formed on a sapphire growth substrate 10 in a direction parallel to the growth substrate at a high temperature of 1100° C. or higher, and in this process, cracking occurs in addition to various crystallographic defects (vacancies, dislocations, stacking faults, nanopipes, and inversion domains) that are commonly observed. In order to solve this problem, using a mechanism in which a process of forming an HT AlN layer 20 of the 3D growth mode in a direction perpendicular to the growth substrate 10 is appropriately combined to relieve tensile stress, a plurality of air voids are introduced inside the HT AlN layer 20 or at the interface with the sapphire growth substrate 10, and thereby the issue of fine microcracking is resolved. However, the HT AlN layer 20 in this layer formation process has crystallinity with both aluminum polarity (Al polarity) and nitrogen polarity (N polarity) and particularly has a rough surface, which adversely affects not only the crystal quality of an active layer of a subsequently formed light-emitting diode but also the quality, such as reliability and lifespan, of a light-emitting diode.

The document [High quality AlN epilayers grown on nitrided sapphire by metal organic chemical vapor deposition, www.nature.com/scientificreports, Published: 21 Feb. 2017] presents a technique for forming a crack-free HT AlN template, in which before growing an HT AlN layer 20 on a sapphire growth substrate 10, the growth substrate 10 is subjected to nitridation to suppress the AlN material having N polarity in the HT AlN layer 20 and overcome the difference in lattice constant and thermal expansion coefficient between the sapphire growth substrate 10 and the HT AlN layer 20. The nitridation may be performed by flowing 2400 sccm NH3 at 950° C. for 7 seconds through metal organic chemical vapor deposition (MOCVD). The HT AlN layer 20 may grow at a temperature of 850° C. or higher (e.g., 1200° C.).

By using this method, a crack-free 2 to 3 μm-thick AlN template may be obtained. However, the current threading dislocation density (TDD) of the HT AlN layer 20 reaches 109 to 1010 cm-2, an AlN material region having N polarity and an irregular distribution and dimensions (size and shape), that is, an inversion domain (ID), is mixed in the HT AlN layer matrix still having Al polarity, and an inversion domain boundary (IDB) is formed at the AlN interface of two polarities, which greatly affects not only the crystal quality of an active layer of a subsequently formed light-emitting diode but also the quality, such as reliability and lifespan, of a light-emitting diode as described above. Therefore, there is a need for a technique for suppressing AlN having N polarity in the HT AlN layer 20 as much as possible.

### DISCLOSURE

### Technical Problem

This will be described at the end of “Modes of the Invention.”

### Technical Solution

This section provides a general summary of the present disclosure and should not be construed as limiting the scope of the present disclosure.

One aspect of the present disclosure provides a method of manufacturing an aluminum nitride (AlN) layer, which includes: preparing a growth substrate; growing an Al_{1-v-w}GaᵥIn_{w}N (0≤v<1, 0≤w<1, v+w<1) layer on the growth substrate; etching the Al_{1-v-w}GaᵥIn_{w}N (0≤v<1, 0≤w<1, v+w<1) layer by decomposing and evaporating gallium (Ga) and indium (In) therein to obtain a porous Al_{1-v-w}GaᵥIn_{w}N (0≤v<1, 0≤w<1, v+w<1) layer having a plurality of air voids; forming a plurality of air voids in the growth substrate using the porous Al_{1-v-w}GaᵥIn_{w}N (0≤v<1, 0≤w<1, v+w<1) layer as an etching mask; and growing an AlN layer on the porous Al_{1-v-w}GaᵥIn_{w}N (0≤v<1, 0≤w<1, v+w<1) layer.

### Advantageous Effects

This will be described at the end of “Modes of the Invention.”

### DESCRIPTION OF DRAWINGS

FIG. 1 shows an example of an ultraviolet (UV) light-emitting semiconductor diode disclosed in U.S. Pat. No. 9,627,580.

FIG. 2 shows an example of a UV light-emitting semiconductor diode according to the present disclosure.

FIG. 3 shows another example of a UV light-emitting semiconductor diode according to the present disclosure.

FIG. 4 shows still another example of a UV light-emitting semiconductor diode according to the present disclosure.

FIG. 5 shows yet another example of a UV light-emitting semiconductor diode according to the present disclosure.

FIG. 6 shows yet another example of a UV light-emitting semiconductor diode according to the present disclosure.

FIG. 7 shows yet another example of a UV light-emitting semiconductor diode according to the present disclosure.

FIG. 8 shows an example of a light-emitting semiconductor diode disclosed in U.S. Pat. No. 10,263,140.

FIG. 9 shows an example of a light-emitting semiconductor diode in the form of a semiconductor chip according to the present disclosure.

FIG. 10 shows a specific example of the light-emitting semiconductor diode shown in FIG. 9.

FIG. 11 shows another specific example of the light-emitting semiconductor diode shown in FIG. 9.

FIG. 12 shows still another specific example of the light-emitting semiconductor diode shown in FIG. 9.

FIG. 13 shows yet another specific example of the light-emitting semiconductor diode shown in FIG. 9.

FIG. 14 shows yet another example of a UV light-emitting semiconductor diode according to the present disclosure.

FIG. 15 shows a curvature change during the growth of the UV light-emitting semiconductor diode shown in FIG. 14.

FIGS. 16 and 17 show examples of a method of manufacturing an aluminum nitride (AlN) template according to the present disclosure.

FIG. 18 shows an example of the method of manufacturing an AlN template shown in FIG. 17.

FIG. 19 shows another example of the method of manufacturing an AlN template shown in FIG. 17.

FIG. 20 shows still another example of the method of manufacturing an AlN template shown in FIG. 17.

FIG. 21 shows another example of a method of manufacturing an AlN template according to the present disclosure.

FIG. 22 shows an example of a method of manufacturing a Group III-nitride semiconductor diode using an AlN template shown in FIG. 21.

### MODES OF THE INVENTION

Hereinafter, the present disclosure will be described in detail with reference to the accompanying drawings.

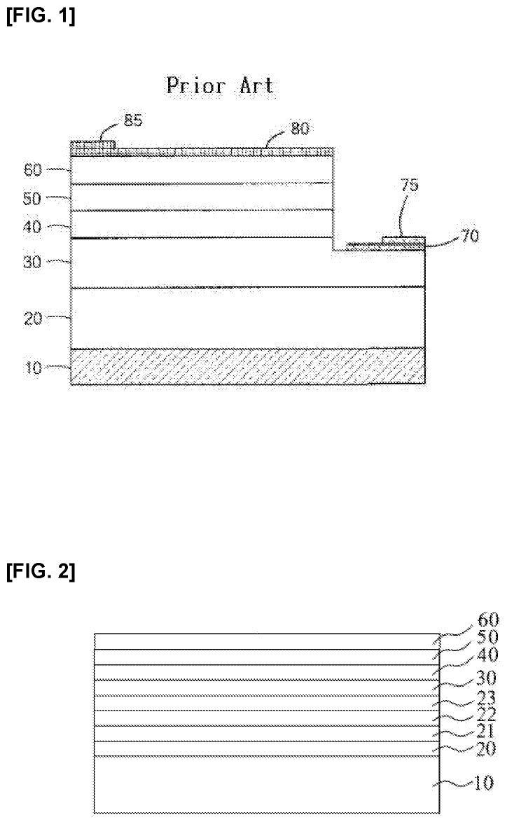

FIG. 2 shows an example of an ultraviolet (UV) light-emitting semiconductor diode according to the present disclosure, and as in FIG. 1, the UV light-emitting semiconductor diode includes a growth substrate 10 (e.g., sapphire), a high temperature (HT)-grown AlN layer 20, a first semiconductor region 30 (e.g., n-type AlGaN layer), an active region 40 (e.g., AlGaN/AlGaN MQWs) that generates light through recombination of electrons and holes, and a second semiconductor region 60 (e.g., p-type (Al)GaN). Preferably, an electron blocking layer 50 (e.g., p-type AlGaN) is further included. Also, an ID and IDB suppressing layer 21, a low temperature (LT)-grown AlN layer 22, and an HT-grown AlxGa1−xN (0.5≤x≤1) layer 23 are included between the HT-grown AlN layer 20 and the first semiconductor region 30.

The ID and IDB suppressing layer 21 may be composed of an AlaNbOc composition by sputtering an AlN material under an oxygen (02) atmosphere or formed by subjecting the HT-grown AlN layer 20 to oxygen surface treatment (plasma, annealing). In general, the HT-grown AlN layer 20 is formed in metal organic chemical vapor deposition (MOCVD) equipment, and the AlN/sapphire template is taken out of the MOCVD equipment and subjected to oxygen surface treatment, or AlaNbOc is directly deposited, and then other layers are grown in the MOCVD equipment. (1) The oxygen surface treatment, which is an example of a process of forming the ID and IDB suppressing layer 21, is performed by exposure to a small amount of oxygen at a temperature of 500° C. or higher for 10 minutes or more, and preferably, RF plasma is used to promote the formation of AlaNbOc on the AlN layer by activating oxygen molecules. (2) The AlaNbOc deposition, which is another example of a process of forming the ID and IDB suppressing layer 21, is performed by directly forming an AlaNbOc material through a physical vapor deposition (PVD) process including sputtering or depositing an AlN material under an oxygen atmosphere to form AlaNbOc.

The LT-grown AlN layer 22, which is grown at a relatively low temperature (850° C. or less) compared to the HT-grown AlN layer 20, serves to promote having an AlN layer having aluminum (Al) polarity without damaging the surface of the ID and IDB suppressing layer 21. In an example, the LT-grown AlN layer 22 grows at 550 to 850° C., a V/III ratio of 3000, a TMA1 MO source of 7.5 μmol/min, and a growth rate of 10 nm/min so that it has a thickness of 50 nm or less. Particularly, it is preferable that the layer is formed under an atmosphere where an Al composition is relatively higher than a nitrogen (N) composition in terms of formation of a surface with Al polarity. In some cases, the LT-grown AlN layer 22 may be removed.

The HT-grown AlxGa1−xN (0.5≤x≤1) layer 23 provides a base for the growth of the first semiconductor region 30 and serves to minimize stress by adjusting the difference in lattice constant between the lower AlN templates 10, 20, 21, 22, and 23 and the first semiconductor region 30. In an example, the layer is formed while adjusting the flow rate of ammonia (NH3) gas so that a V/III ratio is 200 to 40000 at a TMA1 MO source flow rate of 2 to 60 μmol/min and a TMGa MO source flow rate of 10 to 40 μmol/min under conditions of a growth temperature of 1100° C. or higher and a low pressure of 200 mbar or less.

When the HT-grown AlxGa1−xN (0.5<x≤1) layer 23 has a predetermined thickness or more, 3D growth (when the out-plane (z-axis direction) growth rate of the growth surface is higher than the in-plane (x-y axis direction) growth rate) and 2D growth (the in-plane (x-y axis direction) growth rate of the growth surface is higher than the out-plane (z-axis direction) growth rate) are repeated by controlling a V/III ratio according to a change in flow rate of NH3 gas at the set TMAl and TMGa MO sources (μmol/min), and thus a plurality of air voids may be formed. In an example, 3D growth is possible when a V/III ratio is 400 to 800, and 2D growth is possible when a V/III ratio is 50 to 200. Along with the formation of a plurality of air voids through repeated growth and V/III ratio changes, it is possible to control the size and density thereof. As a result, the thermo-mechanical stress of the template including the HT-grown AlxGa1−xN (0.5≤x≤1) layer 23 and the growth substrate 10 is relieved, and microcracking is suppressed.

The HT-grown AlN layer 20 may be formed on the sapphire growth substrate 10 by a basic nitridation or Al preflow (alumination) process at a high temperature of 1000° C. or higher, and for example, formed at a growth rate of 1 μm/h while adjusting a TMAl MO source flow rate to 10 to 50 μmol/min and an NH3 flow rate to 900 to 1200 sccm under conditions of a growth temperature of 1100° C. or higher, a low pressure of 200 mbar or less, and a V/III ratio of 1000 to 2000.

In FIG. 2, the UV light-emitting semiconductor diode according to the present disclosure is shown in the form of an epitaxial wafer, and as in FIG. 1, the UV light-emitting semiconductor diode may be in the form of a lateral chip or a flip chip by forming a first ohmic electrode 70 (e.g., Cr/Ni), a first pad electrode 75 (e.g., Au), a current diffusion electrode 80 (e.g., a light-transmitting electrode (ITO) or a reflective electrode (Al/Ni)), and a second pad electrode 85 (e.g., Cr/Ni/Au or Au).

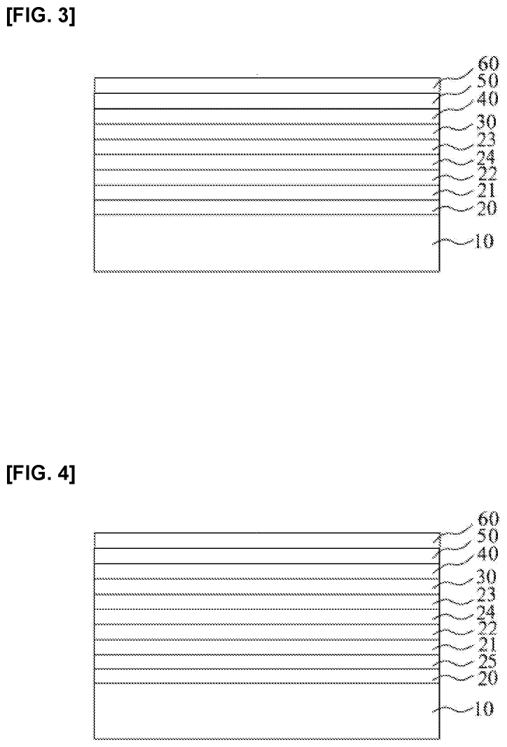

FIG. 3 shows another example of a UV light-emitting semiconductor diode according to the present disclosure, and the UV light-emitting semiconductor diode further includes a HT-grown AlN layer 24 between the LT-grown AlN layer 22 and the HT-grown AlxGa1−xN (0.5≤x≤1) layer 23 in addition to the UV light-emitting semiconductor diode shown in FIG. 2. In an example, the layer is formed at a growth rate of 1 μm/h while adjusting a TMAl MO source flow rate to 10 to 50 μmol/min and an NH3 flow rate to 900 to 1200 sccm under conditions of a growth temperature of 1100° C. or higher, a low pressure of 200 mbar or less, and a V/III ratio of 1000 to 2000. A plurality of air voids may be formed by repeating 3D growth and 2D growth by controlling a V/III ratio according to a change in flow rate of NH3 gas at the set TMAl MO source flow rate (μmol/min). In an example, 3D growth is possible when a V/III ratio is 400 to 800, and 2D growth is possible when a V/III ratio is 50 to 200. Along with the formation of a plurality of air voids through repeated growth and V/III ratio changes, it is possible to control the size and density thereof.

FIG. 4 shows still another example of a UV light-emitting semiconductor diode according to the present disclosure, and the UV light-emitting semiconductor diode further includes a sacrificial layer 25 between the HT-grown AlN layer 20 and the ID and IDB suppressing layer 21 in addition to the UV light-emitting semiconductor diode shown in FIG. 3. By including the sacrificial layer 25, the UV light-emitting semiconductor diode (epitaxial wafer) may be used to form a vertical chip structure. It is preferable that the sacrificial layer 25 is removed through laser lift-off (LLO), and through this, the growth substrate 10 is separated from the plurality of semiconductor layers 25 to 60. The sacrificial layer 25 may also be removed through wet etching. The sacrificial layer 25 may be grown in a single layer or alternating layers of AlN/AlyGa1−yN (0<y≤0.5), and the thickness thereof is 1 μm or less, and preferably, 100 to 600 nm. A growth temperature is 1100 to 1200° C., and the sacrificial layer 25 is grown while maintaining a V/III ratio of 2000 to 3000, a TMAl MO source flow rate of 60 to 80 μmol/min, an NH3 flow rate of 6000 to 8000 sccm, and a growth rate of 1 μm/h. AlN constituting the sacrificial layer 25 may be replaced with AlzGa1−zN (0.5<z<1).

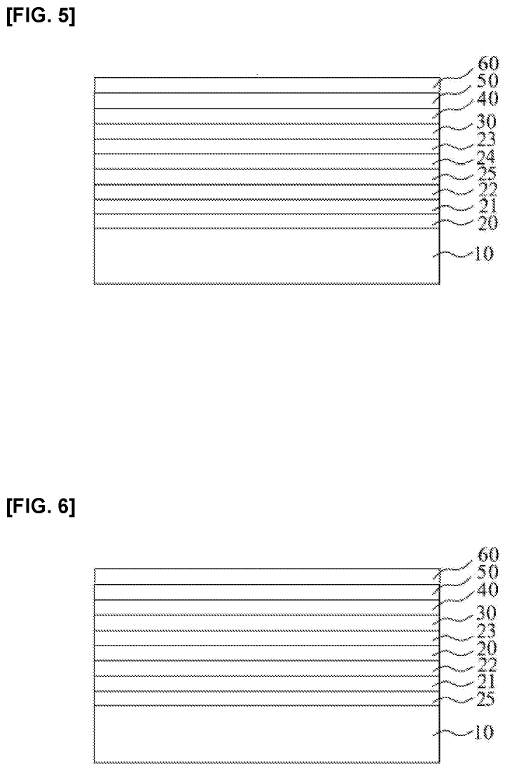

FIG. 5 shows yet another example of a UV light-emitting semiconductor diode according to the present disclosure, and the UV light-emitting semiconductor diode includes a sacrificial layer 25 between an LT-grown AlN layer 22 and an HT-grown AlN layer 24 unlike the UV light-emitting semiconductor diode shown in FIG. 4. In this case, since the sacrificial layer 25 having an Al composition of 50% or less is formed as a single layer or multiple layers on the LT-grown AlN layer 22 having an Al composition of 100%, there is a significant difference in lattice constant. Accordingly, the sacrificial layer may cause thermo-mechanical stress and various crystallographic defects including an inversion domain (ID) or inversion domain boundary (IDB) in the epitaxial structure of a UV light-emitting semiconductor diode having an Al composition of 50% or more, which is subsequently grown on the sacrificial layer 25. This problem may be addressed by providing an ID and IDB suppressing layer 21 and an LT-grown AlN layer 22 below the sacrificial layer 25.

FIG. 6 shows yet another example of a UV light-emitting semiconductor diode according to the present disclosure, and the UV light-emitting semiconductor diode includes a sacrificial layer 25 at the position of the HT-grown AlN layer 20 unlike the UV light-emitting semiconductor diode shown in FIG. 2. Therefore, the sacrificial layer 25 not only functions to remove a growth substrate 10 but also functions as a seed for the growth of a semiconductor layer. Also, the UV light-emitting semiconductor diode includes an HT-grown AlN layer 20 at the position of the HT-grown AlN layer 24 unlike the UV light-emitting semiconductor diode shown in FIG. 3. An ID and IDB suppressing layer 21 and an LT-grown AlN layer 22 serve to suppress crystallographic defects present in the sacrificial layer 25. It is preferable that a nitridation or Al preflow (alumination) process is performed before the sacrificial layer 25 is formed.

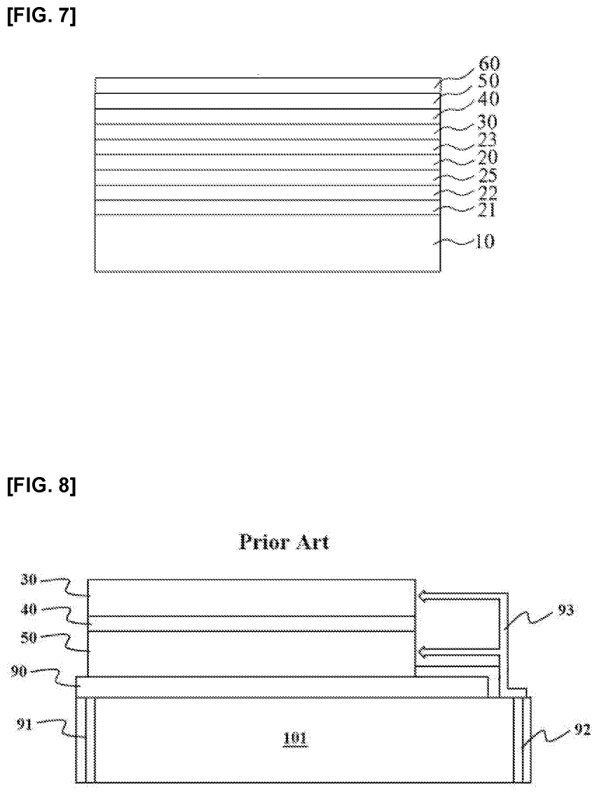

FIG. 7 shows yet another example of a UV light-emitting semiconductor diode according to the present disclosure, and the UV light-emitting semiconductor diode includes a sacrificial layer 25 between an LT-grown AlN layer 22 and an HT-grown AlN layer 20 unlike the UV light-emitting semiconductor diode shown in FIG. 6. It is preferable that a nitridation or Al preflow (alumination) process is performed before an ID and IDB suppressing layer 21 is formed.

FIG. 8 shows an example of a light-emitting semiconductor diode disclosed in US Registered U.S. Pat. No. 10,263,140, and the light-emitting semiconductor diode (in the form of a semiconductor chip; a growth substrate being removed) includes a first semiconductor region 30, an active region 40, a second semiconductor region 50, a bonding layer 90, a first electrical connection 93, and a support substrate 101 including a first electric passage 91 and a second electric passage 92. The plurality of semiconductor regions 30, 40, and 50 electrically communicate with the first electric passage 91 and the second electric passage 92 through the bonding layer 90 and the first electrical connection 93. The growth substrate 10 shown in FIGS. 4 to 7 is separated from the plurality of semiconductor regions 30, 40, and 50 and the support substrate 101 by subjecting the sacrificial layer 25 to a growth substrate removal process (e.g., LLO) in a state in which the support substrate 101 is bonded to the plurality of semiconductor regions 30, 40, and 50 through the bonding layer 90.

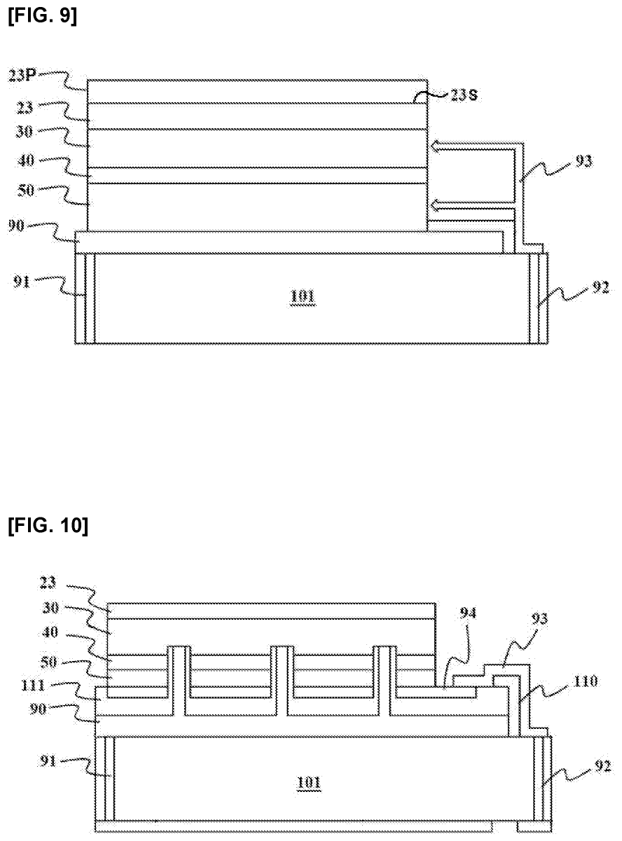

FIG. 9 shows an example of a light-emitting semiconductor diode in the form of a semiconductor chip according to the present disclosure, and shows the result of introducing the process applied to manufacture the light-emitting semiconductor diode shown in FIG. 8 into the epi-type light-emitting semiconductor diode shown in FIGS. 4 to 7. In other words, an HT-grown AlxGa1−xN (0.5≤x≤1) layer 23 is provided on a first semiconductor region 30. The HT-grown AlN layer 24, LT-grown AlN layer 22, ID and IDB suppressing layer 21, and HT-grown AlN layer 20, which remain after the removal of the sacrificial layer 25, are removed. In an example, the sacrificial layer 25 and the sapphire growth substrate 10 are removed through an LLO process, and then the HT-grown AlN layer 24, LT-grown AlN layer 22, IDB suppressing layer 21, and HT-grown AlN layer 20 are completely removed through a dry etching process until the HT-grown AlxGa1−xN (0.5≤x≤1) layer 23 is exposed. Etching is performed so that the surface becomes flat by introducing argon (Ar), chlorine (Cl2), and boron trichloride (BCl3) gas into the chamber of ICP-RIE dry etching equipment at room temperature (25° C.) and appropriately adjusting the flow rates of Cl2 and BCl3 while maintaining a total flow rate of 45 sccm and adjusting an Ar flow rate to 10 sccm or less.

It is preferable that the HT-grown AlxGa1−xN (0.5≤x≤1) layer 23 is formed of a highly resistant insulator not including impurities or dopants (Si, Mg) intentionally introduced to minimize crystallographic defects (vacancies, dislocations, stacking faults, and nanopipes) including IDs or IDBs. Also, it is preferable that a rough surface 23S for increasing light extraction efficiency is formed on the HT-grown AlxGa1−xN (0.5≤x≤1) layer 23. As necessary, a low-refractive-index material 23P (SiO2, Al2O3, AlON, MgF, CaF, or the like) may be further formed on the HT-grown AlxGa1−xN (0.5≤x≤1) layer 23 through PVD or CVD. The HT-grown AlxGa1−xN (0.5≤x≤1) layer 23 having minimized crystallographic defects such as IDs or IDBs not only plays a supporting role in structurally stably preventing the first semiconductor region 30, the active region 40, and the second semiconductor region 50, which are the core regions of the light-emitting semiconductor diode (in the form of a semiconductor chip; a growth substrate being removed), from mechanical impacts that may occur during an LLO process, but also helps prevent the epitaxy of the light-emitting semiconductor diode from being destroyed when a high current is applied by minimizing crystallographic defects such as IDs or IDBs during the growth process.

The low-refractive-index material 23P serves to help UV light (photons) generated in a light-emitting semiconductor diode (in the form of a semiconductor chip; a growth substrate being removed) having a high refractive index of 2.0 or more to be relatively easily extracted into the air (refractive index: 1.1). Particularly, it is preferable that the layer is formed with a material having a lower refractive index than the HT-grown AlxGa1−xN (0.5≤x≤1) layer 23.

FIG. 10 shows a specific example of the light-emitting semiconductor diode shown in FIG. 9, the first electric passage 91 is electrically connected to the first semiconductor region 30 through the bonding layer 90, and the second electric passage 92 is electrically connected to the second semiconductor region 50 through the first electrical connection 93. Reference numerals 110 and 111 represent insulating layers, and a reference numeral 94 represents a first conductive layer. The rough surface 23S and the low-refractive-index material 23P may also be provided.

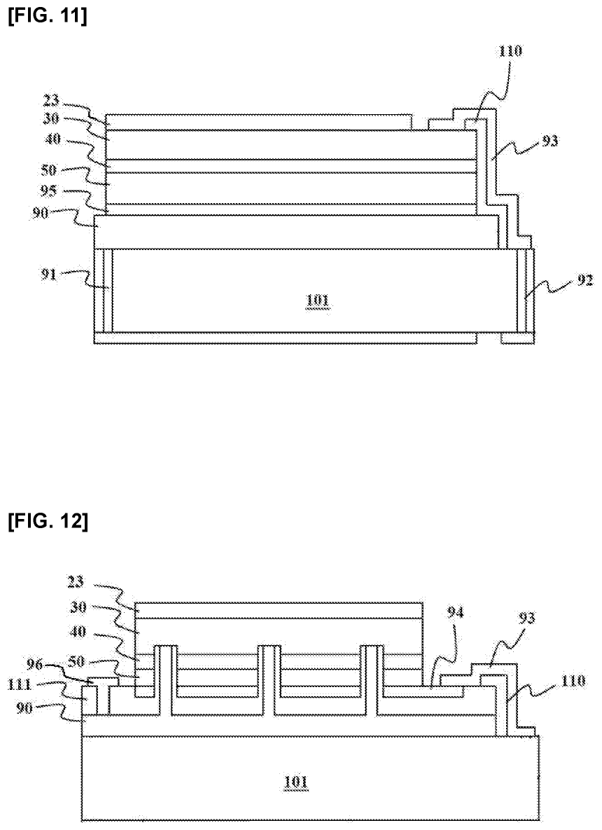

FIG. 11 shows another specific example of the light-emitting semiconductor diode shown in FIG. 9, the first electric passage 91 is electrically connected to the second semiconductor region 50 through the bonding layer 90, and the second electric passage 92 is electrically connected to the first semiconductor region 30 through the first electrical connection 93. The first electrical connection 93 is formed on the first semiconductor region 30 exposed by removing a portion of the HT-grown AlxGa1−xN (0.5≤x≤1) layer 23. A reference numeral 110 represents an insulating layer, and a reference numeral 95 represents a second conductive layer. The rough surface 23S and the low-refractive-index material 23P may also be provided.

FIG. 12 shows still another specific example of the light-emitting semiconductor diode shown in FIG. 9, and the light-emitting semiconductor diode is differentiated from the light-emitting semiconductor diode shown in FIG. 10 in that a first electric passage 91 and a second electric passage 92 are not provided in a support substrate 101, and an opening is formed in an insulating layer 111 to form a second electrical connection 96. A first electrical connection 93 is electrically connected to a second semiconductor region 50 through a first conductive layer 94, and a second electrical connection 96 is electrically connected to a first semiconductor region 30 through a bonding layer 90. The first electrical connection 93 and the second electrical connection 96 serve as bonding pads for wire bonding.

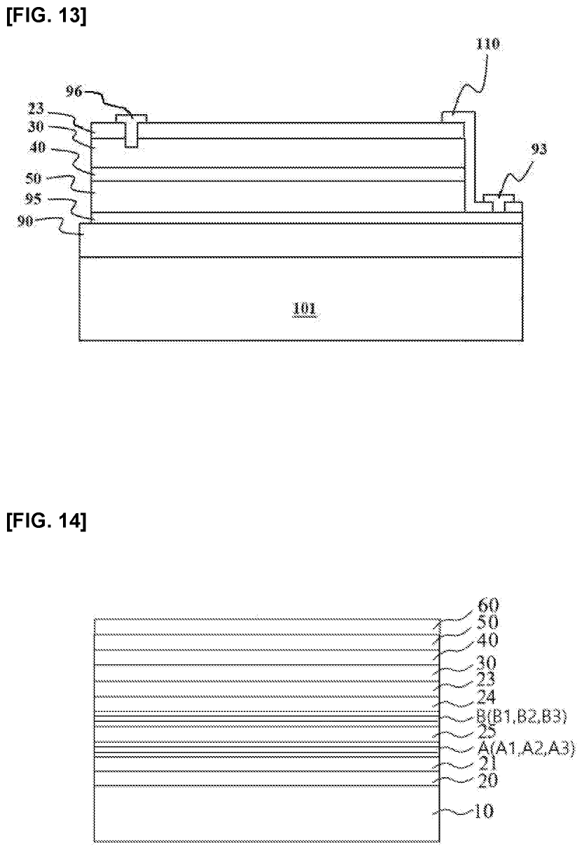

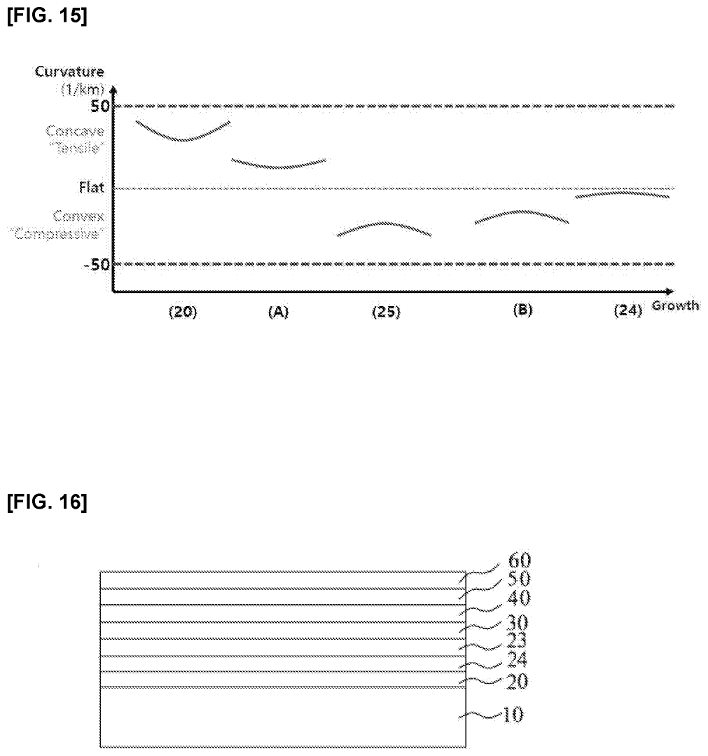

FIG. 13 shows yet another specific example of the light-emitting semiconductor diode shown in FIG. 9, and unlike the light-emitting semiconductor diode shown in FIG. 12, a first electrical connection 93 is electrically connected to a second semiconductor region 50 through a second conductive layer 95, and a second electrical connection 96 is electrically connected to a first semiconductor region 30 by passing through an HT-grown AlxGa1−xN (0.5≤x≤1) layer 23. It is preferable that the second electrical connection 96 is connected to the region of the first semiconductor region 30 where the doping concentration is highest. The first electrical connection 93 and the second electrical connection 96 serve as bonding pads for wire bonding.

FIG. 14 shows yet another example of a UV light-emitting semiconductor diode according to the present disclosure, and the UV light-emitting semiconductor diode is similar to the UV light-emitting semiconductor diode shown in FIG. 5, but a first AlGaN region A is provided instead of the LT-grown AlN layer 22, and a second AlGaN region B is provided between the sacrificial layer 25 and the HT-grown AlN layer 24. In this example, the HT-grown AlN layer 20 is referred to as a first AlN layer 20, the HT-grown AlN layer 24 is referred to as a second AlN layer 24, and the HT-grown AlxGa1−xN (0.5≤x≤1) layer 23 is simply referred to as an AlxGa1−xN (0.5≤x≤1) layer 23. When an LLO process is used to remove the sacrificial layer 25, for example, a laser light source with a wavelength of 248 nm is used, and when the sacrificial layer 25 has a multilayer structure of AlN/AlyGa1−yN, the sacrificial layer 25 is designed to have a y composition of 0.55 or less. In this case, there is an overall difference in an Al composition of 20% or more between the first AlN layer 20 or the second AlN layer 24 and the sacrificial layer 25, and this causes rapid quality degradation, that is, various crystallographic defects (misfit dislocations (MDs)) on the sacrificial layer 25, that is, in the second AlN layer 24, the AlxGa1−xN (0.5≤x≤1) layer 23, and the first semiconductor region 30 (Defect reduced AlN and AlGaN as basic layers for UV LEDs; Viola Kuller; https://depositonce.tu-berlin.de/handle/11303/4320).

In the previous examples, diode improvement was approached from the perspective of ID or IDB generation and suppression, whereas in this example, an approach is made from the perspective of a thermal expansion coefficient and thermo-mechanical stress, and this example is intended to improve diode performance by introducing the first AlGaN region A and the second AlGaN region B. In other words, the first AlGaN region A composed of several layers between the first AlN layer 20 and the sacrificial layer 25 serves to prevent a rapid Al composition change of 20% or more, and the second AlGaN region B composed of several layers between the sacrificial layer 25 and the second AlN layer 24 serves to prevent a rapid Al composition change of 20% or more. For example, when the first AlGaN region A is composed of three layers, a first layer A1 in contact with the first AlN layer 20 has an Al composition of 80% or more, a third layer A3 in contact with the sacrificial layer 25 has an Al composition difference of less than 20% from the sacrificial layer 25, and a second layer A2 provided between the first layer A1 and the third layer A3 has an Al composition difference of less than 20% from each of the first layer A1 and the third layer A3. When three layers are insufficient, the first AlGaN region A may be composed of four layers or more, and when desired conditions are satisfied just with two layers, two layers are sufficient. Summarizing the above description, the first AlGaN region A is composed of several layers so that the layer in contact with the first AlN layer 20 has an Al composition difference of less than 20% from the first AlN layer 20, the layer in contact with the sacrificial layer 25 has an Al composition difference of less than 20% from the sacrificial layer 25, and the layers have an Al composition difference of less than 20% from one another. When the second AlGaN region B is composed of three layers, a first layer B1 in contact with the sacrificial layer 25 has an Al composition difference of less than 20% from the sacrificial layer 25, a third layer B3 in contact with the second AlN layer 24 has an Al composition difference of less than 20% from the second AlN layer 24, and a second layer B2 provided between the first layer B1 and the third layer B3 has an Al composition difference of less than 20% from each of the first layer B1 and the third layer B3. Summarizing the above description, the second AlGaN region B is composed of several layers so that the layer in contact with the sacrificial layer 25 has an Al composition difference of less than 20% from the sacrificial layer 25, the layer in contact with the second AlN layer 24 has an Al composition difference of less than 20% from the second AlN layer 24, and the layers have an Al composition difference of less than 20% from one another. Basically, each layer A1, A2, A3, B1, B2, and B3 composed of a ternary compound AlGaN formed of binary compounds AlN and GaN having opposing vapor chemical properties may be formed through MOCVD at a high temperature of 900° C. or higher and a low pressure of 50 to 200 Torr under a high V/III ratio atmosphere containing a large amount of NH3 gas, and the thickness of each layer A1, A2, A3, B1, B2, and B3 may be designed in consideration of a thickness suitable for being introduced at an interface where crystallographic defects are generated, that is, a critical thickness (Tc). When the second AlN layer 24 is omitted, the second AlGaN region B is formed between the sacrificial layer 25 and the AlxGa1−xN (0.5≤x≤1) layer 23 while satisfying the same conditions. The first AlGaN region A has a form in which an Al composition decreases toward the top, the second AlGaN region B has a form in which an Al composition decreases toward the bottom, and thus they are symmetrically configured. Therefore, it is more preferable to have a balance of thermo-mechanical stress between them. Since they have a symmetric structure based on the sacrificial layer 25, tensile stress and compressive stress, which are caused by a lattice constant and a thermal expansion coefficient, are relieved or adjusted, and thus cracking may be prevented. As described above, it is preferable that the AlxGa1−xN (0.55x≤1) layer 23 is not intentionally doped, and of course, an ID and IDB suppressing layer 21 may be provided. The first semiconductor region 30, active region 40, electron blocking layer 50, and second semiconductor region 60 constitutes a light-emitting diode. As described above, the first AlN layer 20 may include nanoscale voids (or holes, pores, trenches) for relieving tensile stress, or nanoscale surface roughness may be imparted to a sapphire surface through high-temperature annealing before growth. On the other hand, it is preferable that the second AlN layer 24 does not include nanoscale voids (or holes, pores, trenches), and this is because, when the second AlN layer 24 is left in the final diode and nanoscale voids (or holes, pores, trenches) are present in the left second AlN layer 24, they may perform the reverse function of absorbing light.

FIG. 15 shows a curvature change during growth of the UV light-emitting semiconductor diode shown in FIG. 14, the growth substrate 10 (see FIG. 14) has a concave shape by being close to the critical value (50/km) at which cracking occurs during growth of the first AlN layer 20, a concave shape with less bending during growth of the first AlGaN region A, a convex shape during growth of the sacrificial layer 25, a convex shape with less bending during growth of the second AlGaN region B, and an almost flat shape during growth of the second AlN layer 24. This curvature behavior clearly shows the role of the second AlN layer 24 from the perspective of thermo-mechanical stress. It can be seen that when the second AlN layer 24 is included, the upper layers including the AlxGa1−xN (0.5≤x≤1) layer 23 can grow in a further flattened state compared to when growth proceeds by simply including the first AlN layer 20 and the sacrificial layer 25, and the growth substrate 10-the first AlGaN region A-the sacrificial layer 25-the second AlGaN region B-the second AlN layer 24 may be regarded as a template for growth of AlN-based nitride. In this case, the thickness of the second AlN layer 24 may be 3 μm or more, and when the second AlN layer 24 grows to a thickness of 3 μm or more, crystallographic defects including dislocations leading from the growth substrate 10 are annihilated, and thus a template having a low defect density may be formed. When an Al composition x of the AlxGa1−xN (0.5≤x≤1) layer 23 is close to 1, the second AlN layer 24 may be omitted, but it is preferable that the second AlN layer 24 is provided in view of the curvature behavior shown in FIG. 15, and the AlxGa1−xN (0.5≤x≤1) layer 23 also serves to reduce a difference in Al composition between the first semiconductor region 30 and the second AlN layer 24.

From the perspective of curvature behavior, the UV light-emitting semiconductor diode shown in FIG. 15 may be applied to not only a vertical chip in which the growth substrate 10 is removed but also a flip chip, and in this case, the sacrificial layer 25 functions and may be referred to as a stress relieving layer (stress is relieved by reducing an Al composition). Even in a vertical chip, the sacrificial layer 25 functions as a stress relieving layer as well. However, since the stress relieving layer 25 is not finally removed in a flip chip, there is a risk of absorbing UV light generated in the active region 40, and thus it is preferable that the stress relieving layer is configured as a single layer or multiple layers so as to have a higher Al composition than the active region 40. Meanwhile, in the case in which the stress relieving layer 25 is composed of AlN/AlyGa1−yN (0<y≤0.5) (it may also be configured as single-layer AlGaN and multi-layer AlGaN/AlGaN), when an Al composition is increased compared to the case of the sacrificial layer 25 of a vertical chip, the degree of bending of the convex shape of the growth substrate 10 will be relieved compared to when the sacrificial layer 25 is grown in FIG. 15, which contributes to an improvement in the quality of the upper layers.

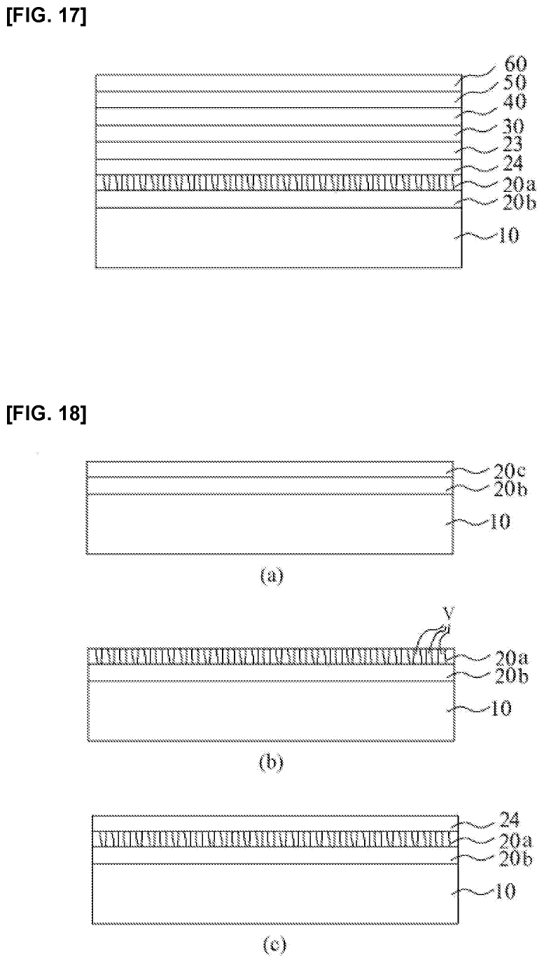

FIGS. 16 and 17 show examples of a method of manufacturing an aluminum nitride (AlN) template according to the present disclosure, and a sacrificial layer 25 is not provided below a second AlN layer 24 unlike that shown in FIG. 14. Therefore, a second AlGaN region B for overcoming a difference in lattice constant and thermal expansion coefficient between a second AlN layer 24 and a sacrificial layer 25 is not required, and a first AlGaN region A is also not required. Even in this case, a crack-free template including a second AlN layer 24 having a low defect density (e.g., middle 108 cm2 to low 109 cm2 TDD) by annihilating crystallographic defects including dislocations leading from a growth substrate 10 (e.g., sapphire, SiC) is required as it is. From the perspective of ID or IDB generation and suppression, the example shown in FIG. 3 presents a method in which the ID and IDB suppressing layer 21 and the LT-grown AlN layer 22 are provided between the first AlN layer 20 and the second AlN layer 24. From the perspective of relief and control of tensile and compressive stresses, this example is intended to present a method of manufacturing an AlN template including a second AlN layer 24 having a thickness of 3 μm or more.

First, as shown in FIG. 16, a method of forming a second AlN layer 24 on a first AlN layer 20 is examined. In this case, methods of relieving tensile stress that have been proposed in the past include 1. adjusting growth conditions to form a plurality of air voids in the first AlN layer 20 during layer formation as described above; 2. manufacturing a nanoscale patterning sapphire substrate (NPSS) on the surface of a growth substrate 10 through ex-situ photolithography before layer formation and then forming a first AlN layer 20; 3. depositing a sputtered AlN material on the growth substrate 10 as a seeding layer and then performing annealing at a high temperature of 1600° C. or higher (HTA); or 4. injecting a small amount of gallium (Ga) component (3% or less; serving as a surface surfactant) into the AlN to promote lateral growth during layer formation. However, when such a method alone or a combination thereof is applied, the thickness of the second AlN layer 24 exceeds the critical thickness (about 1.5 μm), and when the thickness reaches 3 μm or more, which is required to provide an AlN template capable of stable layer formation, it is not easy to prevent cracking and ensure a low defect density.

The document [Fabrication of crack-free AlN film on sapphire by hydride vapor phase epitaxy using an in situ etching method; Xue-Hua Liu et al., Applied Physics Express 9, 045501 (2016)] presents a method of manufacturing a AlN template with an overall thickness of 5 μm by 1) forming a first AlN layer 20 at 1400° C. by a hydride vapor phase epitaxy (HVPE) method, 2) forming a plurality of air voids through etching (at 1550° C. under a hydrogen (H2) gas atmosphere for 2 minutes), and 3) forming a second AlN layer 24 at 1400° C., and by using the above method, a method that not only prevents cracks in the second AlN layer 24 but also reduces crystallographic defects in the AlN template is presented.

However, the method shown in the document uses a HVPE method, which is not easy to apply to a MOCVD method. Also, an etching temperature (Te; 1300° C. or higher) that is at least 100° C. higher than a layer formation temperature (Tg; 1200° C. or higher) is used for etching an AlN thin film material grown at a high temperature of 1200° C. or higher, and in the case of the MOCVD method, it is not realistically easy to apply an etching temperature (Te) that is at least 100° C. higher than a layer formation temperature (Tg) of AlN grown at a high temperature of 1200° C. or higher to commercially available MOCVD equipment.

In FIG. 17, an Al1−vGavN (0<v<1) layer 20a is provided instead of the first AlN layer 20. The Al1−vGavN (0<v<1) layer 20a has a porous structure that has the same function as a plurality of pores and may be called a porous Al1−vGavN (0<v<1) layer 20a. Hereinafter, a second AlN layer 24 is simply referred to as an AlN layer 24. As necessary, a nucleation layer 20b that functions as a seed may be further included between a growth substrate 10 and the Al1−vGavN (0<v<1) layer 20a. It is possible to use AlInN or AlGaInN instead of AlGaN, and the Al1−vGavN (0<v<1) layer 20a may be expanded to an Al1−v−wGavInwN (0≤v<1, 0≤w<1, v+w<1) layer 20a. As an example of a diode that may be placed on the AlN templates 10, 20a, and 24, as in FIG. 14, a first semiconductor region 30, an active region 40, an electron blocking layer 50, and a second semiconductor region 60, which constitute a UV light-emitting semiconductor diode, are formed on the AlN layer 24.

When AlGaN grows directly on a growth substrate 10 or on a growth substrate/AlN (thin film) instead of the first AlN layer 20, there are 1) a primary effect of suppressing tensile stress that causes cracking due to an increase in the in-plane (C plane) lattice constant (a) (some of Al is replaced with Ga), that is, strengthening compressive stress in Al(Ga)N grown on the growth substrate; 2) a secondary effect of forming porous AlN or porous AlGaN (the total composition of Ga is much less than the Ga composition of AlGaN growth) through a gallium decomposition and evaporation process in the grown AlGaN and then relieving tensile stress in a continuously growing Al(Ga)N thin or thick film; and 3) a tertiary effect of suppressing or minimizing deep UV light absorption using the concept of the present disclosure other than an adverse effect of absorbing deep UV light generated in the growth of a Ga-rich AlGaN thin film having a larger Ga composition than an AlGaN material constituting MQWs.

FIG. 18 shows an example of the method of manufacturing an AlN template shown in FIG. 17, first, as shown in FIG. 18A, an Al1−vGavN (0<v<1) layer 20c is formed on a growth substrate 10 (e.g., sapphire, SiC). As described above, a nucleation layer 20b may be provided between the growth substrate 10 and the Al1−vGavN (0<v<1) layer 20c.

For the nucleation layer 20b, in the case of in-situ AlN, a growth temperature is preferably a high temperature of 900° C. or higher, and a range of 500 to 1300° C. is possible, and a growth pressure is preferably a low pressure, and a range of 20 to 200 mbar is possible. Before the nucleation layer 20b is formed on the growth substrate 10, three-dimensional (3D) AlN islands are preferably formed directly on the growth substrate in the 3D growth mode. To this end, layer formation is performed at a relatively high V/III ratio (e.g., 200 or more), that is, under an NH3-rich atmosphere rather than an Al-rich atmosphere in the MOCVD chamber. After the 3D AlN Islands are formed, it is preferable that layer formation is performed at a relatively low V/III ratio (e.g., less than 200) to complete an AlN nucleation layer 20b having a predetermined thickness in a continuous process. In other words, layer formation is performed under an Al-rich atmosphere rather than an NH3-rich atmosphere in the MOCVD chamber. The AlN nucleation layer 20b preferably has a thickness of 200 nm or less. In the case of ex-situ AlN(O), it is preferable that a nucleation layer 20b having a thickness of 50 nm or less is formed with AlN or an AlNO material including a small amount of O2 in a sputtering system at 200 to 700° C.

The Al1−vGavN (0<v<1) layer 20c may be formed on the growth substrate 10 or the nucleation layer 20b, and the layer formation is performed by appropriately adjusting key adjustment parameters that determine the degree of wafer bowing during the growth process, such as growth substrate nitridation, an NH3 flow rate, and a TMGa flow rate. Also, when the nucleation layer 20b is formed in-situ or ex-situ, the thickness of the nucleation layer 20b needs to be adjusted so that excessive wafer bowing does not occur. Basic growth conditions include a temperature of 1100° C. or less and a pressure of 200 mbar or less, and in an example, the Al1−vGavN (0<v<1) layer 20c may be formed at a growth temperature of 1050° C., a growth pressure of 100 mbar, and a growth rate of 0.5 to 2 μm/h. It is more important to perform layer formation using a principle in which as the composition of added Ga increases, the thickness becomes relatively low, and as the composition of added Ga decreases, the thickness becomes relatively high than to specify the thickness and Ga composition of the Al1−vGavN (0<v<1) layer 20c.

When an Al1−v−wGavInwN (0≤v<1, 0≤w<1, v+w<1) layer 20c is used, since indium (In), which has a lower chemical bonding energy (eV) with nitrogen than Al and Ga, is added unlike the Al1−vGavN layer 20c, a growth temperature needs to be considerably lowered. Basic growth conditions include a temperature of 1000° C. or less and a low pressure of 200 mbar or less, and in an example, the Al1−v−wGavInwN (0≤v<1, 0≤w<1, v+w<1) layer 20c may be formed at a growth temperature of 900° C., a growth pressure of 100 mbar, and a growth rate of 0.5 to 2 μm/h. It is more important to perform deposition using a principle in which as the compositions of added Ga and In increase, the thickness becomes relatively low, and as the compositions of added Ga and In decrease, the thickness becomes relatively high than to specify the thickness and Ga composition of the Al1−v−wGavInwN (0≤v<1, 0≤w<1, v+w<1) layer 20c.

Next, as shown in FIG. 18B, a plurality of air voids V are formed in the Al1−vGavN (0<v<1) layer 20c (see FIG. 18A), and thus the Al1−vGavN (0<v<1) layer 20c becomes a porous Al1−vGavN (0<v<1) layer 20a. The plurality of air voids V may be formed by decomposing the Al1−vGavN (0<v<1) layer 20c through etching at an etching temperature (Te) higher than a growth temperature (Tg) of the Al1−vGavN (0<v<1) layer 20c or the porous Al1−vGavN (0<v<1) layer 20a. Etching may be performed under a gas atmosphere including H2, and a plurality of nanoscale voids V may be formed through Ga evaporation.

The plurality of air voids V formed through etching may have a depth that spans the entire porous Al1−vGavN (0<v<1) layer 20a or a depth that extends to only a portion of the porous Al1−vGavN (0<v<1) layer 20a, and the depth may vary depending on etching conditions. The Ga composition (v) in the porous Al1−vGavN (0<v<1) layer 20a remaining after etching depends on the Ga composition (v) in the Al1−vGavN (0<v<1) layer 20c and etching conditions, and may be close to that of AlN. Most preferably, although the AlN material layer does not include Ga and/or In and has a plurality of air voids V, it needs to be smaller than the Ga and In compositions in the MQW of a light-emitting diode such as an LED or LD that is continuously formed to minimize light absorption. In an example, when the Al1−vGavN (0<v<1) layer 20c is formed at a temperature of 1050° C. and a low pressure of 100 mbar, etching may be performed at a temperature of 1150° C. and a low pressure of 50 mbar under an H2 atmosphere including only H2 or a predetermined amount of NH3.

Finally, as shown in FIG. 18C, an AlN layer 24 is grown on the porous Al1−vGavN (0<v<1) layer 20a. Growth conditions of the AlN layer 24 may vary according to two cases depending on the purpose of use as follows.

First, in order to control cracking and increase the thickness of an AlN template by further strengthening the 3D growth mode (rough surface) and further relieving tensile stress, 1. a growth temperature of 1100° C. or less and a relatively low V/III ratio or 2. a growth temperature of 1300° C. or higher and a relatively high V/III ratio is preferred. The thickness is preferably 100 nm to 3.5 μm.

Next, in order to smooth the surface by further strengthening the 2D growth mode (smooth surface), 1. a growth temperature of 1300° C. or more and a relatively low V/III ratio or 2. a growth temperature of 1100° C. or less and a relatively high V/III ratio is preferred. The thickness is preferably 10 nm to 2 μm.

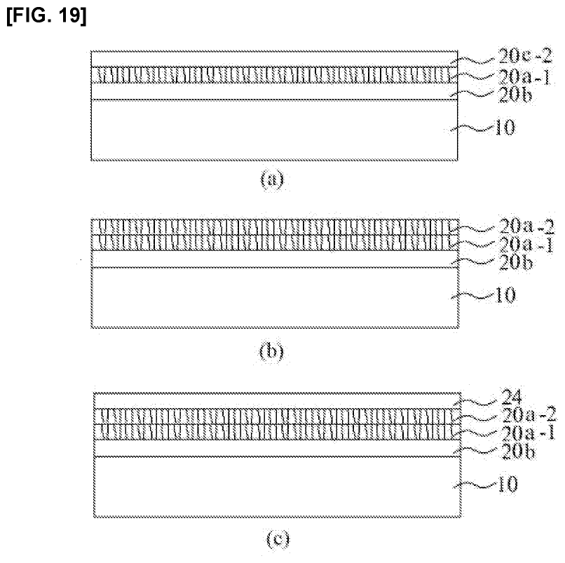

FIG. 19 shows another example of the method of manufacturing an AlN template shown in FIG. 17, and as shown in FIG. 19A, a porous Al1−vGavN (0<v<1) layer 20a-1 is formed, and then an Al1−vGavN (0<v<1) layer 20c-2 is formed. Next, as shown in FIG. 19B, a porous Al1−vGavN (0<v<1) layer 20a-2 is formed through etching. After repeating this process as many times (n) as necessary, an AlN layer 24 is formed as shown in FIG. 19C. By adjusting the Ga decomposition and evaporation in each layer 20a-1 and 20a-2, it is possible for the Al composition of each layer 20a-1 and 20a-2 to be close to that of the AlN layer 24. Although the number of repetitions is not particularly limited, it is determined in consideration of the crystallinity of the AlN thin film. Particularly, the above process may be repeated until the X-ray rocking curve (XRC) FWHM of AlN (0002) and AlN (102) spectrum peaks reaches 300 arcsec or less. Basic growth conditions include a temperature of 1100° C. or less and a low pressure of 200 mbar or less, and in an example, the Al1−vGavN (0<v<1) layer 20c is formed at a growth temperature of 1050° C., a growth pressure of 100 mbar, and a growth rate of 0.5 to 2 μm/h. It is more important to form the layer using a principle in which as the composition of added Ga increases, the thickness becomes relatively low, and as the composition of added Ga decreases, the thickness becomes relatively high than to specify the thickness and Ga composition of the Al1−vGavN (0<v<1) layer 20c. In an example, when the Al1−vGavN (0<v<1) layer 20c is formed at a temperature of 1050° C. and a low pressure of 100 mbar, etching may be performed at a temperature of 1150° C. and a low pressure of 50 mbar under an H2 atmosphere including only H2 or a predetermined amount of NH3.

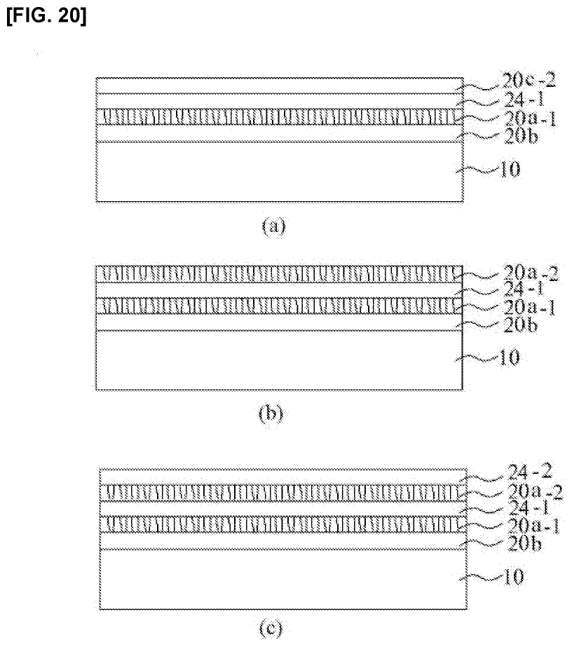

FIG. 20 shows still another example of the method of manufacturing an AlN template shown in FIG. 17, and as shown in FIG. 20A, a porous Al1−vGavN (0<v<1) layer 20a-1 and an AlN layer 24-1 are formed, and then an Al1−vGavN (0<v<1) layer 20c-2 is formed. Next, as shown in FIG. 20B, a porous Al1−vGavN (0<v<1) layer 20a-2 is formed through etching. Next, as shown in FIG. 20C, an AlN layer 24-2 is formed. This process is repeated as many times (n) as necessary. An AlN template is configured so that the finally formed nth AlN layer 24-n is thicker than previous AlN layers 24-1 to 24-n−1. In the formation of the porous Al1−vGavN (0<v<1) layer 20a-1 and the porous Al1−vGavN (0<v<1) layer 20a-2, the layer formation conditions and number of repetitions described in FIG. 19 may be used, and the thickness of the AlN layer 24-1 and the nth AlN layer 24-n may be adjusted in consideration of the thickness of the entire AlN layer. The AlN layers 24-1 to 24-n−1 are referred to as AlN interlayers, and the AlN interlayers 24-1 to 24-n−1 may each have, for example, a thickness of 100 nm or less.

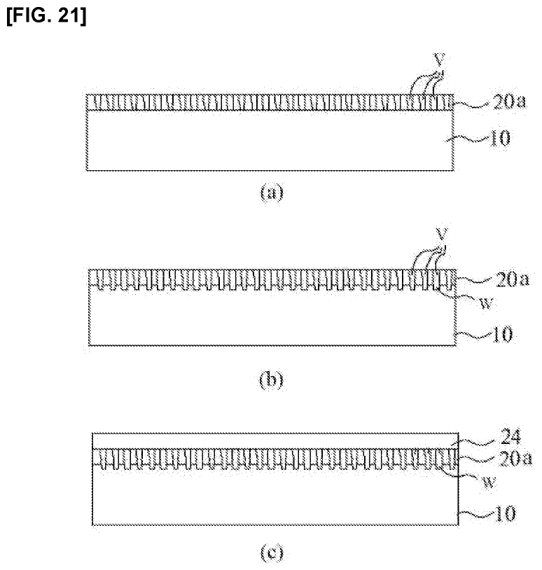

FIG. 21 shows another example of a method of manufacturing an AlN template according to the present disclosure, and as shown in FIG. 21A, a porous Al1−v−wGavInwN (0≤v<1, 0≤w<1, v+w<1) layer 20a is formed as in FIG. 18B. Next, rather than directly performing the process shown in FIG. 18C, as shown in FIG. 21B, a plurality of air voids W corresponding to a plurality of air voids V are formed in a growth substrate 10 using the porous Al1−v-wGavInwN (0≤v<1, 0≤w<1, v+w<1) layer 20a as an etching mask. The plurality of air voids W serve to relieve tensile stress like a plurality of air voids V. The formation of a plurality of air voids W may be performed at a high temperature (e.g., 1000° C. or higher) under a H2 reducing atmosphere, and an etching rate increases as a chamber pressure increases. The formation of a plurality of air voids V and the formation of a plurality of air voids W may be performed by one etching process. The plurality of air voids W may have a width of 10 to 50 nm and a depth of 10 to 300 nm, and deeper voids are preferred. Next, as shown in FIG. 21C, an AlN layer 24 is grown on the porous Al1−v−wGavInwN (0≤v<1, 0≤w<1, v+w<1) layer 20a as in FIG. 18C. In this case, by forming the plurality of air voids by adjusting the growth conditions of the AlN layer 24 on the porous Al1−v−wGavInwN (0≤v<1, 0≤w<1, v+w<1) layer 20a (using growth conditions so that vertical growth is faster than horizontal growth; since the 3D growth mode (vertical growth is faster) is strengthened when a V/III ratio is relatively increased, and the 2D growth mode (horizontal growth is faster) is strengthened when a V/III ratio is relatively decreased, the 3D growth mode time (t3D) with a high V/III ratio is made larger than the 2D growth mode time (t2D) with a low V/III ratio.), tensile stress may be relieved, and the top of a plurality of air voids may be closed or open. The plurality of air voids may have a depth of 500 nm to 2 μm and a width of 10 to 100 nm.

As shown in FIG. 19, a plurality of porous Al1−v-wGavInwN (0≤v<1, 0≤w<1, v+w<1) layers 20a-1 and 20a-2 may be repeated.

In addition, as shown in FIG. 20, a plurality of porous Al1−v-wGavInwN (0≤v<1, 0≤w<1, v+w<1) layers 20a-1 and 20a-2 and a plurality of AlN layers 24-1 and 24-2 may be repeated, then a plurality of air voids V may be formed, and of course, it is possible to form a plurality of air voids W in the growth substrate 10. In this case, even when a plurality of air voids are not formed in a plurality of AlN layers 24-1 and 24-2 or the top thereof is not open, a H2 radical gas generated by decomposition of a H2 carrier or NH3 reaches the growth substrate 10 through crystal defects, that is, threading dislocations, present in the plurality of AlN layers 24-1 and 24-2 and thus the sapphire growth substrate 10 may be optionally etched to form a plurality of air voids W. When the plurality of AlN layers 24-1 and 24-2 are grown so that there are a plurality of air voids, etching may be effectively performed. When the nucleation layer 20b shown in FIG. 18A is provided, a plurality of air voids W may be formed in the growth substrate 10 as well.

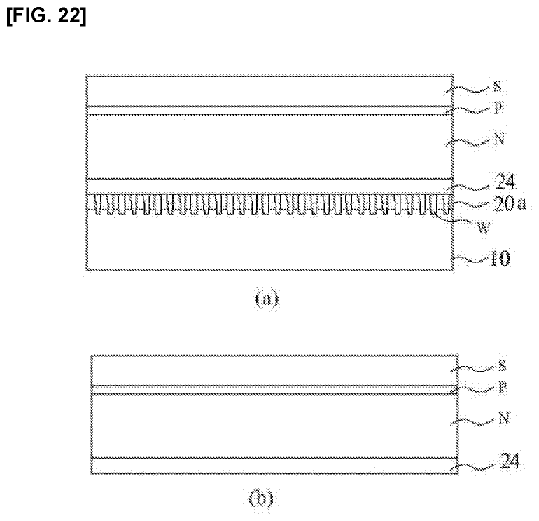

FIG. 22 shows an example of a method of manufacturing a Group III-nitride semiconductor diode using the AlN template shown in FIG. 21, and the Group III-nitride semiconductor diode may be an LED, an LD, an HEMT, a piezoelectric thin film, or the like having an Al-containing semiconductor layer and is not particularly limited. FIG. 22A shows AlN templates 10, 20a, and 24, a Group III-nitride semiconductor diode region N (e.g., the plurality of the semiconductor regions 30, 40, and 50 shown in FIG. 17) serving as a Group III-nitride semiconductor diode, a bonding layer P, and a support substrate S. In FIG. 22B, the growth substrate 10 is removed, laser lift-off (LLO) may be used in the removal of the growth substrate 10, and although a sacrificial layer 25 is not provided unlike the examples shown in FIGS. 4 to 7, the porous Al1−v−wGavInwN (0≤v<1, 0≤w<1, v+w<1) layer 20a having a plurality of air voids V replaces the sacrificial layer 25. When the growth substrate 10 is irradiated with a laser beam light source, the growth substrate 10 and the Group III-nitride semiconductor diode region N may be separated through the energy band gap difference or a process of converting light energy into heat energy by isolating and absorbing the laser beam light source inside the plurality of air voids V. Therefore, the porous Al1−v−wGavInwN (0≤v<1, 0≤w<1, v+w<1) layer 20a may improve the crystallinity of the Al-containing Group III-nitride semiconductor layers and serve as a sacrificial layer 25 in separation of the growth substrate 10. Also, since the porous Al1−v−wGavInwN (0≤v<1, 0≤w<1, v+w<1) layer 20a has a plurality of air voids V, the growth substrate 10 and the Group III-nitride semiconductor diode region N are bonded with a relatively weak bonding force to buffer the diode from thermo-mechanical stress that occurs in subsequent processes such as wafer bonding. As necessary, the AlN layer 24 may be removed by a method such as dry etching or the like.

Hereinafter, various embodiments of the present disclosure will be described.

(1) A method of manufacturing an aluminum nitride (AlN) layer, including: preparing a growth substrate; growing an Al1−v−wGavInwN (0≤v<1, 0≤w<1, v+w<1) layer on the growth substrate; etching the Al1−v−wGavInwN (0≤v<1, 0≤w<1, v+w<1) layer by decomposing and evaporating gallium (Ga) and indium (In) therein to obtain a porous Al1−v−wGavInwN (0≤v<1, 0≤w<1, v+w<1) layer having a plurality of air voids; forming a plurality of air voids in the growth substrate using the porous Al1−v−wGavInwN (0≤v<1, 0≥w<1, v+w<1) layer as an etching mask; and growing an AlN layer on the porous Al1−v−wGavInwN (0≤v<1, 0≤w<1, v+w<1) layer.

(2) In this method, the growing and etching of an Al1−v−wGavInwN (0≤v<1, 0≤w<1, v+w<1) layer are repeated several times before the forming of a plurality of air voids in the growth substrate.

(3) In this method, the etching and the growing of an AlN layer are repeated several times (n times) in the growing of an Al1−v−wGavInwN (0≤v<1, 0≤w<1, v+w<1) layer.

(4) In this method, the Al1−v−wGavInwN (0≤v<1, 0≤w<1, v+w<1) layer is an Al1−vGavN (0<v<1) layer.

(5) This method further includes: growing an aluminum (Al)-containing Group III-nitride semiconductor diode region on the AlN layer; and separating the growth substrate from the Group III-nitride semiconductor diode region using the porous Al1−v−wGavInwN (0≤v<1, 0≤w<1, v+w<1) layer as a sacrificial layer.

(6) In this method, the Group III-nitride semiconductor diode region includes an active region emitting ultraviolet light.

According to the ultraviolet light-emitting semiconductor diode of the present disclosure, IDBs can be suppressed.

According to the ultraviolet light-emitting semiconductor diode of the present disclosure, a semiconductor chip using an IDB suppression structure can be manufactured

According to the ultraviolet light-emitting semiconductor diode of the present disclosure, an ultraviolet light-emitting semiconductor diode having reduced crystallographic defects can be manufactured.

According to the method of manufacturing an aluminum nitride template of the present disclosure, an aluminum nitride template having no cracks and a low crystallographic defect density can be manufactured.

1. A method of manufacturing an aluminum nitride (AlN) layer, comprising:
preparing a growth substrate;
growing an Al_{1-v-w}GaᵥIn_{w}N (0≤v<1, 0≤w<1, v+w<1) layer on the growth substrate;
etching the Al_{1-v-w}GaᵥIn_{w}N (0≤v<1, 0≤w<1, v+w<1) layer by decomposing and evaporating gallium (Ga) and indium (In) therein to obtain a porous Al_{1-v-w}GaᵥIn_{w}N (0≤v<1, 0≤w<1, v+w<1) layer having a plurality of air voids;
forming a plurality of air voids in the growth substrate using the porous Al_{1-v-w}GaᵥIn_{w}N (0≤v<1, 0≤w<1, v+w<1) layer as an etching mask; and
growing an AlN layer on the porous Al_{1-v-w}GaᵥIn_{w}N (0≤v<1, 0≤w<1, v+w<1) layer.

2. The method of claim 1, wherein the growing and etching of an Al_{1-v-w}GaᵥIn_{w}N (0≤v<1, 0≤w<1, v+w<1) layer are repeated several times before the forming of a plurality of air voids in the growth substrate.

3. The method of claim 1, wherein the etching and the growing of an AlN layer are repeated several times (n times) in the growing of an Al_{1-v-w}GaᵥIn_{w}N (0≤v<1, 0≤w<1, v+w<1) layer.

4. The method of claim 1, wherein the Al_{1-v-w}GaᵥIn_{w}N (0<v<1, 0≤w<1, v+w<1) layer is an Al₁₋ᵥGaᵥN (0<v<1) layer.

5. The method of claim 1, further comprising:
growing an aluminum (Al)-containing Group III-nitride semiconductor diode region on the AlN layer, and
separating the growth substrate from the Group III-nitride semiconductor diode region using the porous Al_{1-v-w}GaᵥIn_{w}N (0≤v<1, 0≤w<1, v+w<1) layer as a sacrificial layer.

6. The method of claim 5, wherein the Group III-nitride semiconductor diode region includes an active region emitting ultraviolet light.
